(19) United States
(12) Patent Application Publication
(10) Pub. No.: US 2009/0009263 A1
(43) Pub. Date: Jan. 8, 2009

(54) Duplexer

(76) Inventors: Gholamreza Dadgar Javid, Munich (DE); Michael Jakob, Munich (DE); Jurgen Kiwitt, Munich (DE); Gunter Kovacs, Munich (DE); Helmut Klamm, Munich (DE)

Correspondence Address: FISH & RICHARDSON PC, P.O. BOX 1022, MINNEAPOLIS, MN, 55440-1022, US

(21) Appl. No.: 11/817,936

(22) PCT Filed: Jan. 5, 2006
(86) PCT No.: PCT/EP2006/000069

§ 371 Date: Sep. 8, 2008

(30) Foreign Application Priority Data
Mar. 8, 2005 (DE) 10 2005 010 658.7

(51) Int. Cl. H03H 9/72

(52) U.S. Cl. 333/133

(57) ABSTRACT

A duplexer includes an antenna terminal, a transmit filter, and a receive filter. The receive filter includes a first sub-filter that includes one or more resonators, and a second sub-filter including a double mode surface acoustic wave (DMS) filter. The second sub-filter is downstream of the first sub-filter relative to the antenna.

### TECHNICAL FIELD

This patent application describes a duplexer having a receive filter that operates with surface acoustic waves.

### BACKGROUND

A duplexer that operates with surface acoustic waves and that includes a receive filter constructed of DMS filters is known, for instance, from US 2003/0214369 A1 (DMS=Double Mode Surface Acoustic Wave).

A DMS filter with alternately arranged input transducers and output transducers is described in U.S. Pat. No. 6,556,100 and in U.S. Pat. No. 5,835,990.

### SUMMARY

Described herein is a duplexer with improved power compatibility.

A duplexer with a transmit filter and a receive filter is described herein. The receive filter has a first sub-filter arranged on the antenna side and a second sub-filter downstream thereof.

The first sub-filter may have at least one resonator operating with acoustic waves. The second sub-filter has a DMS filter.

In an embodiment, the first sub-filter passes electrical signals in the passband of the DMS filter and blocks those in the passband of the transmit filter, whereby the input of the DMS filter is protected from excessive transmitting power in the transmit mode.

The at least one resonator can be a series resonator, i.e. a resonator connected in the signal path. The at least one resonator can also be a parallel resonator, i.e. a resonator arranged in a shunt arm connected between the signal path and reference potential.

Several resonators may be provided in the first sub-filter. At least one of the resonators is a series resonator and the remaining resonators (e.g. those arranged in different shunt arms) are parallel resonators.

At least one ladder type element with a series resonator and a parallel resonator can be realized in the first sub-filter. A T-element with two series resonators and a parallel resonator as in FIG. 2, or a π-element with two parallel resonators and a series resonator as in FIG. 2E can also be realized.

A multi-port resonator can be arranged in the first sub-filter. Multi-port resonators are described in WO03/081773, which is incorporated in full herein by reference. A multi-port resonator has at least two transducers acoustically coupled to one another, which may be arranged in an acoustic track bounded by two resonators. The transducers of the multi-port resonator can be arranged, for example, in the series branch (in the signal line) or in the shunt arms of the sub-filter.

A multi-port resonator can be connected, for example, downstream of the second sub-filter in one embodiment. This is advantageous with a balanced output of the second sub-filter with two signal lines, wherein the different transducers of the multi-port resonator are arranged in different signal lines.

The resonator (or resonators) arranged in the first sub-filter may operate with surface acoustic waves. The at least one input-side resonator can be a resonator operating with bulk acoustic waves in one embodiment. In case of several resonators, it is possible to construct at least one BAW (bulk acoustic wave) resonator arranged on the antenna side and thus most subjected to the transmission power during transmission.

A DMS filter comprises at least one acoustic track, which comprises a transducer arrangement with alternately arranged input transducers and output transducers. The acoustic track may be bordered by reflectors at both ends, between which the transducer arrangement is arranged. The input transducers and the output transducers of the same acoustic track are acoustically coupled to one another and may be galvanically separated from one another.

The receive path of the duplexer may be constructed with only one antenna-side signal line (single-ended) and with two signal lines at the output (balanced) to carry a symmetrical signal.

The input of the receive filter may be single-ended in construction. The input transducers of the acoustic track connected to the resonator may be connected in parallel to one another. The output transducers of this track are connected, in one embodiment, to the output of the receive filter. In another embodiment, they are provided as coupling transducers, which are galvanically connected to input transducers of another acoustic track as coupling transducers. The output transducers of the additional track may be connected to the output of the receive filter or to coupling transducers of an additional acoustic track.

The output of the receive filter may be balanced in construction, with two signal lines. In one embodiment, at least one output transducer of the acoustic track terminally arranged in the DMS filter, or a group of parallel-connected output transducers, is arranged in each signal line.

It is possible to form the terminally arranged output transducer in the DMS filter or in the receive path in such a way that the output impedance of the DMS track is transformed in relation to its input impedance. For example, the terminally arranged output transducer can have a V-split for impedance transformation, wherein sub-transducers arranged side by side in the longitudinal direction are connected to one another in series and may have a common busbar.

The terminally arranged output transducer in another embodiment can have an H-split for impedance transformation, wherein sub-transducers arranged side by side in the transverse direction are serially connected to one another and have a common busbar. In this regard, WO98/57429 is incorporated in full herein by reference.

In an embodiment, the output impedance of the receive filter can differ from its input impedance. In one embodiment, the two sub-filters can have different impedances. The output impedance of the second sub-filter can be different from its input impedance. It is also possible for the necessary impedance transformation to be realized in the first sub-filter, in which case the input impedance of the second sub-filter is equal to its output impedance.

The impedance transformation can be realized in a filter or a sub-filter by, for example, subdividing a transducer into transducers that are cascaded, i.e. connected one behind the other, one above the other or one alongside the other. The impedance transformation in a filter can also be realized by providing transducers arranged side by side longitudinally in an acoustic track, and connected in parallel to one another in the same signal path.

It is advantageous to construct at least one of the antenna-side resonators of the first sub-filter with transducers connected one behind the other. The objective of cascading is to decrease the power density per acoustic track, from which an increased power compatibility results. The impedance of the cascaded transducer arrangement is may be equal to the impedance of a non-cascaded transducer.

Between the antenna terminal of the duplexer and the receive filter, it is possible to arrange a phase shifter, which may be implemented as a λ/4 line for a transmitter frequency. This creates a no-load operation at the input of the receive filter and thus protects this input in transmission mode.

The transmit filter has a resonator operating with surface acoustic waves, at least in one embodiment. In another embodiment, the transmit filter has at least one resonator operating with bulk acoustic waves. All resonators of the transmit filter may be implemented in a technology with SAW resonators or BAW resonators (SAW=Surface Acoustic Wave; BAW=Bulk Acoustic Wave).

The component structures, i.e., particularly the resonators of the transmit filter and the receive filter, may be formed on a common piezoelectric substrate. This substrate with the component structures formed as structured printed conductors forms a chip, which can be electrically connected to connecting surfaces of a base plate by, for instance, bumps or bond wires. The chip can be permanently connected mechanically to the base plate by, for instance, bumps or an adhesion promoting layer. The base plate can have a multilayer structure with alternately arranged structured layers of metal and dielectric layers. In the metal layers, particularly those on the inside, electrical elements, inductors and capacitors are realized with structured printed conductors. The electrical structures arranged in different layers of metal are connected to one another and to external contacts of the base plate by interlayer contacts.

The duplexer will be explained below in detail on the basis of embodiments and the associated figures. The figures show various embodiments on the basis of schematized representations and are not true to scale. Identical or identically functioning components are labeled with identical reference symbols.

### DESCRIPTION OF THE DRAWINGS

FIG. 1 shows an equivalent circuit diagram of a duplexer with a two-part receive filter;

FIG. 2, an example of a receive filter with a DMS track, which can be used in the duplexer according to FIG. 1;

FIG. 2A, a resonator realized as a SAW resonator, used in the first sub-filter;

FIG. 2B, a resonator realized as a BAW resonator, used in the first sub-filter;

FIG. 2C, an arrangement realized as a resonator stack of two resonators connected one behind the other, used in the first sub-filter;

FIG. 2D, a section of a resonator with cascaded sub-resonators, which may be arranged on the antenna side in the first sub-filter;

FIG. 2E, a receive filter with resonators, connected on the output side to the DMS track;

FIG. 2F, a part of the receive filter with a multi-port resonator in the series branch;

FIG. 2G, a part of the receive filter with a multi-port resonator in the shunt arm.

FIG. 3, an example of a receive filter with two coupled DMS tracks, which can be applied in the duplexer of FIG. 1;

FIG. 3A, a receive filter with a DMS track, which has several input transducers connected in parallel to one another;

FIG. 3B, a DMS track, which has several input transducers connected in parallel to one another, as well as several output transducers connected in parallel to one another;

FIG. 4, an electrical element with a duplexer realized in a chip, wherein the chip is mounted on a base plate in flip-chip technology; and

FIG. 5, an electrical element with a duplexer realized in a chip, wherein the chip is mounted on a base plate and electrically connected thereto by bond wires.

### DETAILED DESCRIPTION

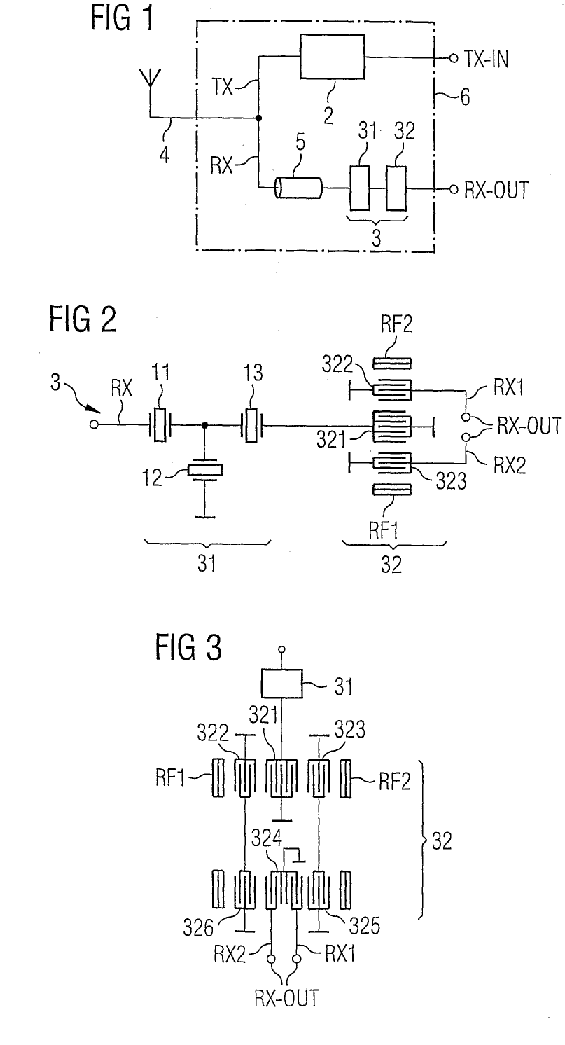

FIG. 1 shows a duplexer having a transmit filter 2 and a receive filter 3, an antenna terminal 4, a transmit input TX-IN, and a receive output RX-OUT. Receive filter 3 comprises a first sub-filter 31 and a second sub-filter 32.

The duplexer has a transmit path TX and a receive path RX. Transmit path TX is arranged between antenna terminal 4, and transmit input TX-IN. Receive path TX is arranged between antenna terminal 4 and receive output RX-OUT.

A phase shifter, constructed here as a line section of length \tilde{λ}/4, is arranged between antenna terminal 4 and receive filter 3. A phase shifter may rotate signal phases by 180° and can comprise LC elements as an alternative to a line section. Instead of the phase shifter, it is possible to provide an adaptive network, which transmits in the passband of receive filter 3 and assures a no-load operation or a high isolation in the passband of transmit filter 2 at the input of filter 3.

All elements 2-5 of the duplexer, including terminals TX-IN, RX-OUT, are formed on a common piezoelectric substrate 6.

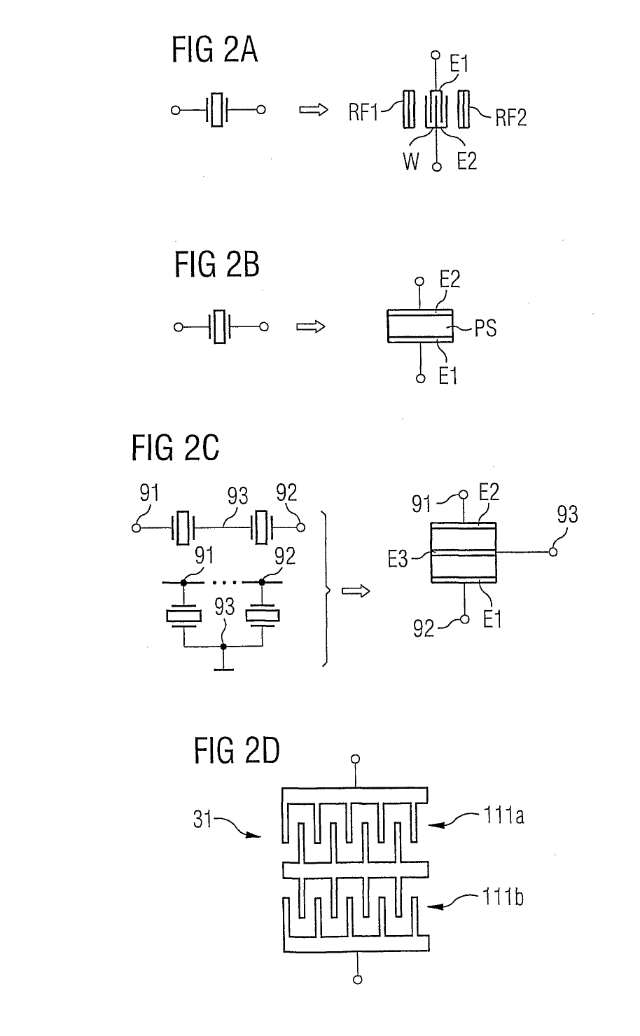

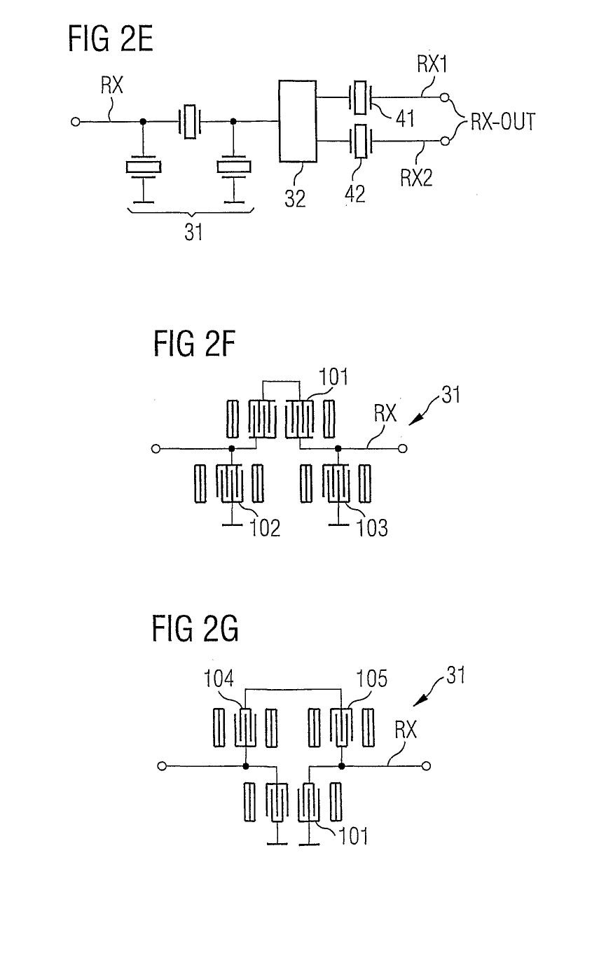

FIG. 2 shows the structure of receive filter 3. First sub-filter 31 has two series resonators 11, 13 and a parallel resonator 12 connected to reference potential in the shunt arm. Several shunt arms connected to different electrical nodes of a single signal path, each with at least one parallel resonator, can also be provided.

Second sub-filter 32 has a DMS track delimited by reflectors RF1, RF2, with an input transducer 321 and two output transducers 322, 323. Input transducer 321 is arranged between output transducers 322, 323 and is acoustically coupled thereto. Signal path RX is divided on the output side into two sub-paths or signal lines RX1, RX2. First output transducer 322 is arranged in a first signal line RX1 of the receive path, and second output transducer 323 is arranged in a second signal line RX2 of the receive path.

First output transducer 322 may be connected to a first terminal of receive output RX-OUT, and second output transducer 323 is connected to a second terminal of receive output RX-OUT. Alternatively, at least one additional resonator, not shown here, can be connected on the output side in signal lines RX1, RX2 of the output side receive path to output transducer 322 or 323 of the DMS track.

Examples of resonators that can be used in the first sub-filter, for instance, as series resonators and/or parallel resonators, are shown in FIGS. 2A-C.

FIG. 2A shows a surface acoustic wave resonator, which has an acoustic track limited by reflectors RF1, RF2, and an interdigital transducer W arranged therein with two interpenetrating comb-like electrodes E1, E2. The aforementioned structures are constructed as metal structures made, for instance, of A1 on a piezoelectric substrate made, for example, of quartz, lithium tantalate, or lithium niobate.

FIG. 2B shows a bulk acoustic wave resonator with two electrodes E1, E2 made, for instance, of A1, and a piezoelectric layer PS made, for instance, of A1N arranged therebetween.

It is indicated in FIG. 2C that two resonators connected between two electrical nodes 91, 92 and connected to a common electrical node 93, for instance, two resonators connected one behind the other (upper left), or two resonators arranged in different shunt arms connected to a common reference potential (lower left), can be constructed in the form of a resonator stack with resonators arranged one above the other. The acoustically coupled resonators arranged one above the other have a common electrode E3, which is arranged between two piezoelectric layers. The first piezoelectric layer is arranged between electrodes E1, E3, and the second piezoelectric layer between the electrodes E3, E2.

In one embodiment, two resonators connected one behind the other or two resonators arranged in different shunt arms, connected to a common reference potential, can be realized by an acoustic track operating with surface acoustic waves with two transducers arranged one alongside the other in the longitudinal direction that are acoustically and electrically coupled to one another, or by sub-transducers of a transducer having a V-split.

FIG. 2D shows a transducer that can be used in a SAW resonator with two acoustic tracks arranged one above the other in the transversal direction. In order to form a transducer, sub-transducers 111a, 111b are cascaded, i.e., connected one after the other. Sub-transducers 111a, 111b have a common busbar, which may be floating.

A cascade connection of n sub-resonators is referred to as an n-fold resonator cascade. When n sub-resonators are cascaded, the acoustic surface of an individual sub-resonator should be enlarged by a factor of n² so that its impedance remains constant. An acoustic surface is understood to mean the surface occupied by the acoustic track, that is, the product of the aperture (width) and the length of the acoustic track. Because of the enlargement of the resonator surface, it is possible to reduce the power density in the resonator and thus to increase the resonator's service life.

Additional resonators can be arranged on the output side of DMS filter 32. One embodiment is shown in FIG. 2E, in which one resonator 41, 42 is arranged in each of the signal paths RX1, RX2. It is also possible to arrange a resonator circuit, for example, a resonator circuit in ladder-type construction such as first sub-filter 31, in each of the signal paths RX1, RX2.

Instead of two resonators 41, 42, it is possible to use a dual-port resonator—multiport resonator 101—shown for instance, in FIG. 2F, with two acoustically coupled transducers. The first transducer of dual-port resonator 101 is to be arranged in subpath RX1 and the second transducer in subpath RX2.

Possible embodiments for the formation of first sub-filter 31 of receive filter 3 are shown in FIGS. 2F and 2G.

In FIG. 2F, a multiport resonator 101 with two acoustically coupled transducers and a parallel resonator 102, 103 arranged in each shunt arm is shown.

A series connection of series resonators 104, 105 is arranged in the signal line of receive path RX in FIG. 2G. Acoustically coupled transducers of a multiport resonator 101 are arranged in shunt arms.

In FIGS. 2F and 2G, it is possible to arrange multiport resonators downstream of DMS track 32 as well.

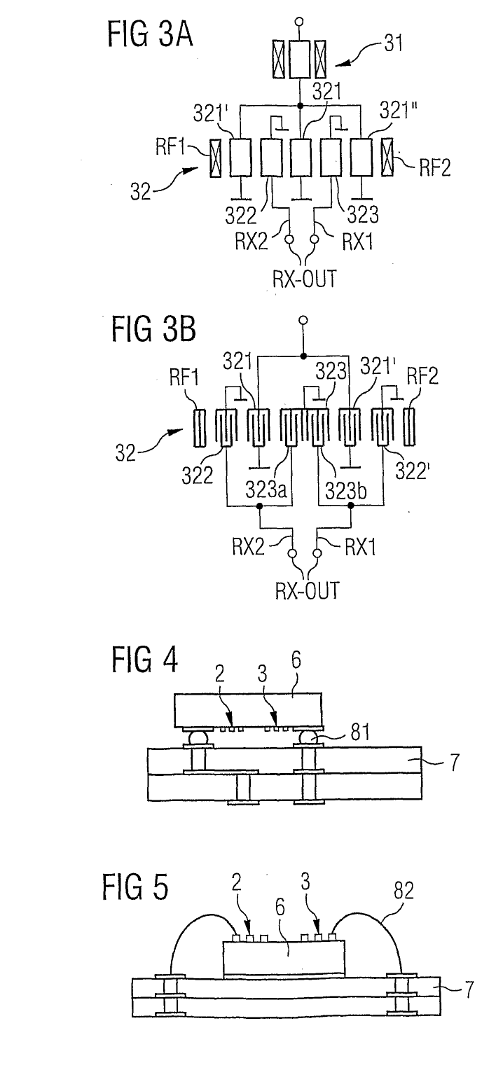

A receive filter with a second sub-filter constructed as a two-track DMS filter is shown in FIG. 3. The first DMS track is constructed as in FIG. 2 and is coupled via its output transducers 322, 323 to input transducers 325, 326 of the second DMS track. Transducers 322, 326 and 322, 323 connect one after the other thus also serve as coupling transducers for electrocoustically coupling the two DMS tracks.

Between input transducers 325, 326 of the second DMS track is arranged an output transducer, which has a V-split and is divided into two sub-transducers connected in series. The sub-transducers are each connected in a signal line RX1, RX2. The common busbar here is at reference potential.

FIG. 3A shows a receive filter, in which first sub-filter 31 has a SAW resonator according to FIG. 2A. Second sub-filter 32 is shown as a DMS track with several (in this case three) input transducers 321, 321′, 321″ connected in parallel. On the output side in the receive path an output transducer 322, 323 is connected in each signal line RX1, RX2. Output transducers 322 and 323, respectively, are arranged between two input transducers 321, 321′ and 321, 321″.

Due to the parallel connection of several input transducers, the input impedance of second sub-filter 32 is reduced by comparison to the embodiment with only one input transducer, which has the same acoustic surface.

FIG. 3B shows an embodiment of the formation of a DMS filter, in which instead of only one transducer, a parallel connection of two output transducers is arranged on the output side in each signal line RX1, RX2. Output transducer 322 here and a first sub-transducer 323a of divided output transducer 323 are connected in parallel. The same applies to output transducer 322′ and second sub-transducer 323b of divided output transducer 323.

In the embodiment shown in FIG. 3B, two input transducers 321, 321′ are connected in parallel on the input side. Input transducer 321 is arranged between output transducers 322, 323 and input transducer 321′ is arranged between output transducers 323, 322′.

FIG. 4 shows an example of an embodiment of the duplexer as a component suitable for surface mounting, with a base plate 7, on which a chip having a piezoelectric substrate 6 with structures of filters 2, 3 arranged thereon is mounted in a flip-chip arrangement by bumps 81.

Base plate 7 has a multilayer structure with several alternately arranged dielectric and metallic layers. A dielectric layer, which may be ceramic, is formed between two metal layers of base plate 7. In the lowermost metal layer of base plate 7, connection surfaces are provided specifically for contacting the component. In the uppermost metal layer of base plate 7, connection surfaces suitable for contacting the chip are formed. All metal layers, and particularly the metal layers on the inside, are suitable for forming component structures, for example, duplexer structures and additional structures connected electrically thereto.

At least a part of the structures of filters 2, 3 is arranged on the surface facing base plate 7 or the bottom surface of substrate 6. Additional structures of these filters, and, e.g., of phase shifter 5 shown in FIG. 1, can be arranged in a metal layer lying, for instance, on the inside of base plate 7.

Besides the chip shown in FIG. 4, additional chips such as chip capacitors, chip inductors, filters or semiconductor chips can be mounted on base plate 7.

FIG. 5 shows an embodiment of the component with the duplexer, in which the chip with duplexer structures formed therein is mounted fixedly on the base plate by adhesion, for example, and connected electrically by bonding wires to its contact surfaces.

The claims are not limited to the figures presented here, the number of certain elements, or their specific relative arrangement. In principle, more than only two or three input or output transducers can be connected in parallel in the same DMS track. Various characteristics, explained here in connection with only one embodiment, may be used with other embodiments.

What is claimed is:

1. A duplexer comprising:
an antenna terminal;
a transmit filter; and
a receive filter comprising:
a first sub-filter comprising one or more resonators; and
a second sub-filter comprising a double mode surface acoustic wave (DMS) filter, the second sub-filter being downstream of the first sub-filter relative to the antenna.

2. The duplexer of claim 1, wherein at least one resonator comprises a series resonator.

3. The duplexer of claim 1, wherein at least one resonator comprises a parallel resonator.

4. The duplexer of claim 1, wherein at least one resonator comprises a series resonator and at least one resonator comprises a parallel resonator.

5. The duplexer of claim 1, wherein at least one resonator comprises cascaded transducers.

6. The duplexer of claim 1, wherein the second sub-filter has an output side; and
wherein the second sub-filter is balanced on the output side.

7. The duplexer of claim 6, wherein the second sub-filter comprises sub-transducers connected in series, the sub-transducers being formed from a V-split balanced output transducer.

8. The duplexer of claim 1, wherein the DMS filter comprises more than one acoustic track; and
wherein different acoustic tracks of the DMS filter are interconnected electroacoustically via coupling resonators.

9. The duplexer of claim 1, wherein an output impedance of the second sub-filter differs from an input impedance of the second sub-filter.

10. The duplexer of claim 1, further comprising:
a phase shifter between the antenna terminal and the receive filter.

11. The duplexer of claim 1, wherein the transmit filter comprises at least one surface acoustic wave resonator.

12. The duplexer of claim 1, wherein the transmit filter comprises at least one bulk acoustic wave resonator.

13. The duplexer of claim 1, further comprising:
a piezoelectric substrate on which component structures of the transmit filter and component structures of the receive filter are formed.

14. The duplexer of claim 13, further comprising:
a base plate having a buried electrical element, the piezoelectric substrate being electrically connected to the base plate.

15. The duplexer of claim 14, wherein the piezoelectric substrate is mechanically connected to the base plate.

16. The duplexer of claim 1, wherein at least one resonator comprises a bulk acoustic wave resonator.

17. The duplexer of claim 1, further comprising:
one or more additional resonators downstream of the second sub-filter relative to the antenna.

18. The duplexer of claim 8, wherein an output impedance of the second sub-filter differs from an input impedance of the second sub-filter.

19. The duplexer of claim 8, further comprising:
a phase shifter between the antenna terminal and the receive filter.

20. The duplexer of claim 8, wherein the transmit filter comprises at least one surface acoustic wave resonator.

21. The duplexer of claim 17, wherein the second sub-filter comprises a balanced output port, and wherein at least one resonator is electrically connected in series to each one of two terminals of the balanced output port.

22. The duplexer of claim 1, wherein the first sub-filter comprises two resonators electrically connected in series to each other, wherein the two resonators are part of a multi-port resonator and acoustically coupled to each other, and wherein at least one additional resonator is electrically connected in parallel to the two resonators.
